(19) United States
(12) Patent Application Publication
(10) Pub. No.: US 2009/0251656 A1
(43) Pub. Date: Oct. 8, 2009

(54) DISPLAY SUBSTRATE AND METHOD FOR MANUFACTURING THE SAME

(76) Inventors: Bong-Kyu Shin, Bucheon-si (KR); Seung-Jae Jung, Seoul (KR); Sang-Uk Lim, Suseong-gu (KR); Sang-Woo Whangbo, Seoul (KR); Jae-Ho Choi, Seoul (KR); Hwa-Yeul Oh, Seoul (KR); Yong-Mo Choi, Osan-si (KR)

Correspondence Address: F. CHAU & ASSOCIATES, LLC, 130 WOODBURY ROAD, WOODBURY, NY, 11797, US

(21) Appl. No.: 12/391,541

(22) Filed: Feb. 24, 2009

(30) Foreign Application Priority Data
Apr. 3, 2008 (KR) 2008-31067

(51) Int. Cl. G02F 1/1333; H05K 3/00

(52) U.S. Cl. 349/158; 427/97.3

(57) ABSTRACT

A display substrate includes a soda-lime glass substrate, a barrier pattern, and first, second and third conductive patterns. The soda-lime glass substrate has a pixel area. The first conductive pattern includes a gate line formed on the soda-lime glass substrate and from a first conductive layer. The barrier pattern is formed between the first conductive pattern and the soda-lime glass substrate. The second conductive pattern includes a data line crossing the gate line. The data line is formed on the first conductive pattern and from a second conductive layer. The third conductive pattern includes a pixel electrode formed in the pixel area of the soda-lime glass substrate. The pixel electrode is formed on the second conductive pattern and from a third conductive layer.

### PRIORITY STATEMENT

This application claims priority under 35 U.S.C. §119 to Korean Patent Application No. 2008-31067, filed on Apr. 3, 2008, the disclosure of which is hereby incorporated by reference herein in it's entirety.

### BACKGROUND OF THE INVENTION

1. Technical Field

Example embodiments of the present invention relates to a display substrate and to a method for manufacturing the display substrate.

2. Description of the Related Art

In a liquid crystal display (LCD) apparatus, an image may be displayed by applying a voltage to a liquid crystal layer interposed between two glass substrates and controlling light transmissivity. Generally, borosilicate glass substrates are used for the glass substrates. A borosilicate glass substrate has high resistance to thermal shock, rapid temperature variation and chemical corrosion. However, the price of the borosilicate glass substrate may be high so that the borosilicate glass substrate may make up a large portion of the cost of materials for the LCD apparatus.

On the other hand, a soda-lime glass substrate may be cheaper, and may have high resistance to corrosive compounds because the soda-lime glass substrate is an oxide mixture including silica, calcium, sodium and so on. However, the soda-lime glass substrate may become warped in a high-temperature process, so that it may be difficult to maintain the uniformity of a thin film. In addition, another difficulty which may be associated with the soda-lime glass substrate is that alkali ions, such as the sodium, may flow into the thin film from the soda-lime glass substrate so that device characteristics of the product may be deteriorated or the reliability of the product may be reduced. Accordingly, the soda-lime glass substrate may be difficult to apply to the LCD apparatus.

However, the demand for large-sized LCD apparatus is rapidly increasing, and thus a technique for applying the cheaper soda-lime glass substrate to the LCD apparatus instead of the expensive borosilicate glass substrate may be required to enhance price competitiveness.

### SUMMARY OF THE INVENTION

Exemplary embodiments of the present invention may provide a display substrate to enhance the reliability of a product.

Exemplary embodiments of the present invention may also provide a method for manufacturing the display substrate.

In accordance with an exemplary embodiment of the present invention, a display substrate is provided. The display substrate includes a soda-lime glass substrate, a first conductive pattern, a barrier pattern, a second conductive pattern and a third conductive pattern. The soda-lime glass substrate has a pixel area. The first conductive pattern includes a gate line. The gate line is formed on the soda-lime glass substrate and is formed from a first conductive layer. The barrier pattern is formed between the first conductive pattern and the soda-lime glass substrate. The second conductive pattern includes a data line crossing the gate line. The data line is formed on the first conductive pattern and is formed from a second conductive layer. The third conductive pattern includes a pixel electrode formed in the pixel area of the soda-lime glass substrate. The pixel electrode is formed on the second conductive pattern and is formed from a third conductive layer.

In accordance with an exemplary embodiment of the present invention, a display substrate is provided. The display substrate includes a soda-lime glass substrate, a gate line, a gate circuit part, a circuit barrier pattern, a data line and a pixel electrode. The soda-lime glass substrate has a plurality of pixel areas. The gate line is formed by making direct contact with the soda-lime glass substrate. The gate circuit part applies a driving signal to the gate line. The circuit barrier pattern is disposed between the gate circuit part and the soda-lime glass substrate. The data line crosses the gate line. The pixel electrode is formed in each of the pixel areas.

In accordance with an exemplary embodiment of the present invention, a method for manufacturing a display substrate is provided. The method includes forming a barrier layer and a first conductive layer on a soda-lime glass substrate, wherein the soda-lime glass substrate includes a pixel area. A first conductive pattern having a gate line and a barrier pattern is formed between the first conductive pattern and the soda-lime glass substrate, by patterning the barrier layer and the first conductive layer using substantially the same mask. A second conductive pattern including a data line crossing the gate line is formed. The data line is formed on the first conductive pattern and is formed from a second conductive layer. A third conductive pattern including a pixel electrode is formed in the pixel area of the soda-lime glass substrate. The pixel electrode is formed on the second conductive pattern and is formed from a third conductive layer.

In accordance with another exemplary embodiment of the present invention, a method for manufacturing a display apparatus is provided. The method includes forming a barrier layer on a soda-lime glass substrate. The soda-lime glass substrate has a display area a gate circuit area in which a gate circuit part is formed and a pixel area. A circuit barrier pattern is formed in the gate circuit area, by patterning the barrier layer. A first conductive pattern including a gate line is formed. The gate line is formed on the soda-lime glass substrate having the circuit barrier pattern formed thereon and is formed from the first conductive layer. A second conductive pattern including a data line crossing the gate line is formed. The data line is formed on the soda-lime glass substrate having the first conductive pattern formed thereon and is formed from the second conductive layer. A third conductive pattern including a pixel electrode formed in the pixel area of the soda-lime glass substrate is formed. The pixel electrode is formed on the second conductive pattern and is formed from a third conductive layer.

According to exemplary embodiments of the present invention, a patterned barrier layer is formed on a soda-lime glass substrate, so that an area in which the barrier layer is formed may be decreased, malfunctions due to foreign matter may be decreased, and the light transmissivity may be enhanced.

### BRIEF DESCRIPTION OF THE DRAWINGS

Exemplary embodiments of the present invention can be understood in more detail from the following description taken in conjunction with the accompanying drawings, in which:

FIG. 1 is a plan view illustrating a display substrate according to an exemplary embodiment of the present invention;

FIG. 2 is an enlarged view partially illustrating the display substrate in FIG. 1;

FIG. 3 is a cross-sectional view taken along a line I-I′ in FIG. 2;

FIGS. 4 to 7 are cross-sectional views illustrating a process for manufacturing the display substrate in FIG. 3;

FIG. 8 is a cross-sectional view illustrating a display substrate according to an exemplary embodiment of the present invention;

FIGS. 9 to 11 are cross-sectional views illustrating a process for manufacturing the display substrate in FIG. 8;

FIG. 12 is a cross-sectional view illustrating a display substrate according to an exemplary embodiment of the present invention;

FIG. 13 is a graph illustrating a correlation between a voltage between drain and source electrodes and the resistance of a gate electrode; and

FIGS. 14 to 17 are cross-sectional views and plan views illustrating a process for manufacturing the display substrate in FIG. 12.

### DETAILED DESCRIPTION OF THE EXEMPLARY EMBODIMENTS OF THE INVENTION

The invention is described more fully hereinafter with reference to the accompanying drawings, in which exemplary embodiments of the invention are shown. This invention may, however, be embodied in many different forms and should not be construed as limited to the embodiments set forth herein. In the drawings, the size and relative sizes of layers and areas may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, areas, layers and/or sections, these elements, components, areas, layers and/or sections should not be limited by these terms. These terms are only used to distinguish one element, component, area, layer or section from another area, layer or section. Thus, a first element, component, area, layer or section discussed below could be termed a second element, component, area, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, exemplary embodiments of the invention should not be construed as limited to the particular shapes of areas illustrated herein but are to include deviations in shapes that result, for example, from manufacturing. For example, an implanted area illustrated as a rectangle will, typically, have rounded or curved features and/or a gradient of implant concentration at its edges rather than a binary change from implanted to non-implanted area. Likewise, a buried area formed by implantation may result in some implantation in the area between the buried area and the surface through which the implantation takes place. Thus, the areas illustrated in the figures are schematic in nature and their shapes are not intended to illustrate the actual shape of an area of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the exemplary embodiments of the present invention will be explained in detail with reference to the accompanying drawings.

### Exemplary Embodiment 1

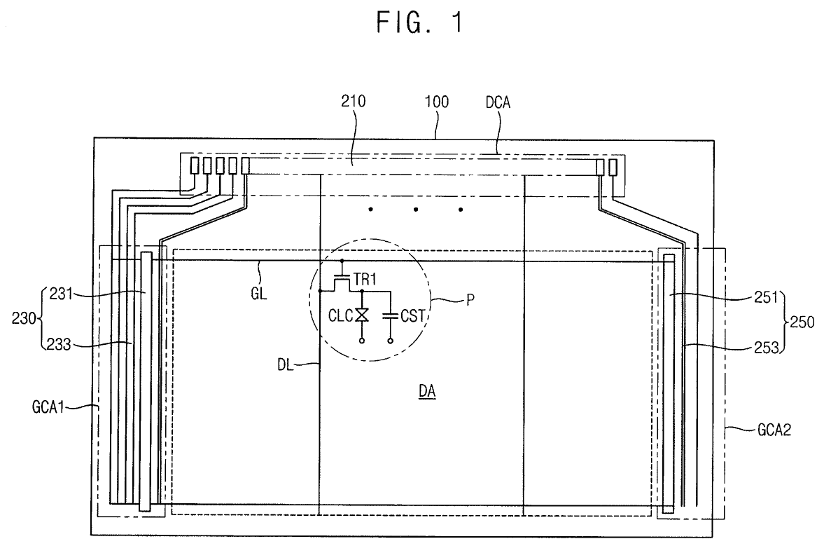

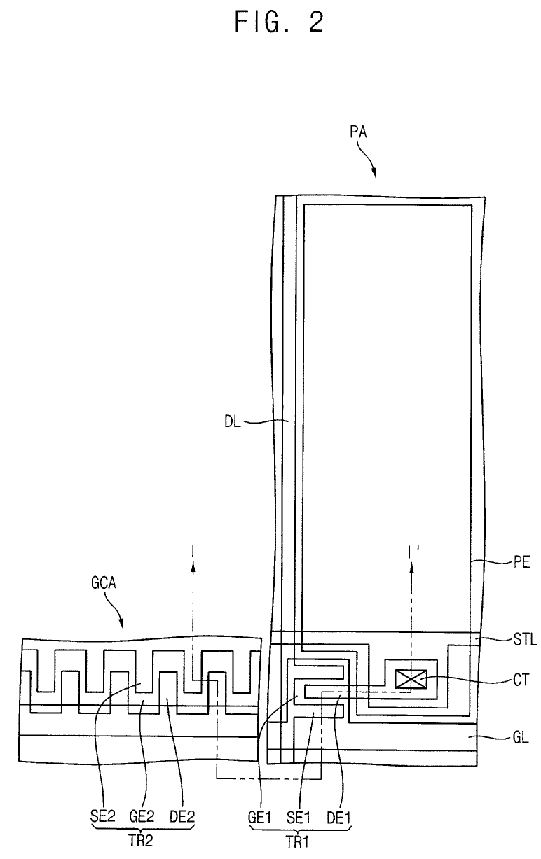

FIG. 1 is a plan view illustrating a display substrate according to Exemplary Embodiment 1 of the present invention. FIG. 2 is an enlarged view partially illustrating the display substrate in FIG. 1.

Referring to FIGS. 1 and 2, the display apparatus 100 includes a display area DA and a peripheral area surrounding the display area DA. The peripheral area has a data circuit area DCA and gate circuit areas GCA1 and GCA2. A plurality of pixel portions P is formed in the display area DA. Each of the pixel portions P includes a gate line GL, a data line DL crossing the gate line GL, a first switching element TRI electrically connected to the gate and data lines GL and DL, a liquid crystal capacitor CLC electrically connected to the first switching element TR1, and a storage capacitor CST.

The data circuit area DCA is defined as an area adjacent to a portion of the data line DL, and a data pad part 210 is formed in the data circuit area DCA. The data pad part 210 includes input pads receiving a signal from outside and output pads electrically connected to the data line DL. For example, a data driving circuit may be mounted on the data circuit area DCA as a chip type, or a flexible printed circuit board (FPCB) having the data driving circuit mounted thereon may be mounted on the data circuit area DCA. Alternatively, the data driving circuit and a line for driving the data driving circuit may be directly formed on the data circuit area DCA.

The gate circuit areas GCA1 and GCA2 are defined as areas adjacent to both end portions of the gate line GL. For example, a first gate circuit part 230 which outputs a high voltage to the gate line GL is formed in a first gate circuit area GCA1 adjacent to a first end portion of the gate line GL. The first gate circuit part 230 includes a gate driving circuit 231 and a first line 233. The gate driving circuit 231 includes a second switching element TR2 to sequentially output the high voltage. The first line 233 is electrically connected to the data pad part 210 to transfer a driving signal of the gate driving circuit 231 to the gate driving circuit 231.

A second gate circuit part 250 is formed in a second gate circuit area GCA2 adjacent to a second end portion of the gate line GL. The second gate circuit part 250 includes a subsidiary driving circuit 251 and a second line 253. The subsidiary driving circuit 251 maintains a voltage of the gate line GL to be a low voltage. The second line 253 is electrically connected to the data pad part 210 to transfer a driving signal of the subsidiary driving circuit 251 to the subsidiary driving circuit 251. The subsidiary driving circuit 251 also includes the second switching element TR2.

As mentioned above, the subsidiary driving circuit 251 is formed in the second gate circuit area GCA2. Alternatively, a gate driving circuit substantially the same as the gate driving circuit 231 may be formed in the second gate circuit area GCA2. In this case, the gate driving circuit formed in the first gate circuit area GCA1 may drive odd-numbered gate lines, and the gate driving circuit formed in the second gate circuit area GCA2 may drive even-numbered gate lines.

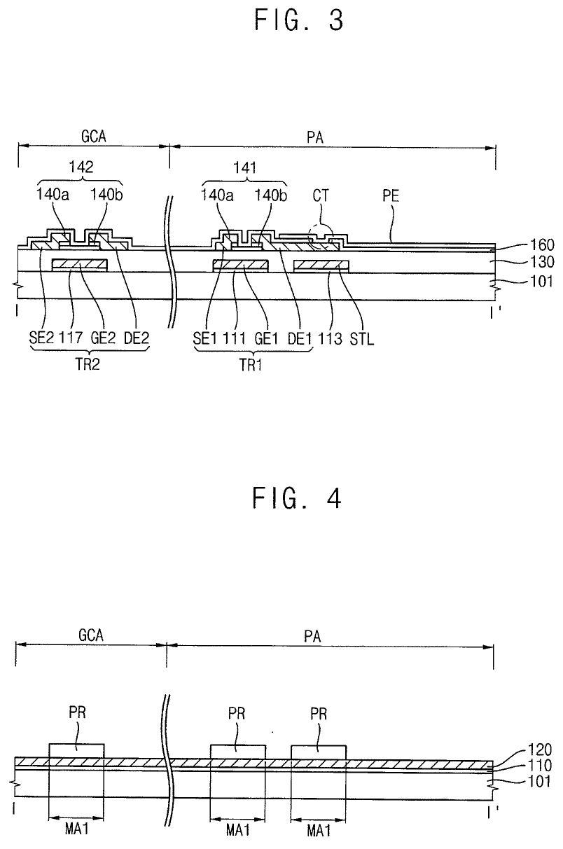

FIG. 3 is a cross-sectional view taken along a line I-I′ in FIG. 2.

Referring to FIGS. 2 and 3, the display apparatus 100 includes, for example, a soda-lime glass (SLG) substrate 101. The SLG substrate 101 is, for example, an alkali glass substrate.

The SLG substrate 101 includes a pixel area PA in which the pixel portion P is formed, and first and second gate circuit areas GCA1 and GCA2 in which the first and second gate circuit parts 230 and 250 are respectively formed. The first and second gate circuit areas GCA1 and GCA2 will be referred to as the gate circuit area GCA in the following descriptions.

Barrier patterns 111, 113 and 117 are formed on the SLG substrate 101. The barrier patterns 111, 113 and 117 are formed between the SLG substrate 101 and a first conductive pattern. The barrier patterns 111, 113 and 117 are patterned in substantially the same way as the first conductive pattern.

The barrier patterns 111, 113 and 117 strengthen the adhesive strength between the SLG substrate 101 and the first conductive pattern. For example, the barrier patterns 111, 113 and 117 prevents the first conductive pattern from being disconnected or released from the SLG substrate 101 due to alkali ions from the SLG substrate 101. The barrier patterns 111, 113 and 117 may include, for example, a conductive material, a non-conductive material, a transparent material or an opaque material. For example, the barrier patterns 111, 113 and 117 may include one of molybdenum, amorphous indium-tin-oxide (a-ITO), indium-tin-oxide (ITO), indium-zinc-oxide (IZO), silicon nitride (SiNx), silicon oxide (SiOx) and a metal compound. The metal compound may be, for example, one of a metal oxide, a metal nitride, a metal boride and a metal carbide. The thickness of the barrier layer 110 may be between about 50 angstroms (Å) and about 2,000 Å.

The first conductive pattern includes a gate line GL formed in the pixel area PA, a first gate electrode GE1 of the first switching element TR1, a storage line STL, and a second gate electrode GE2 of the second switching element TR2.

For example, the barrier patterns 111, 113 and 117 are formed beneath the first gate electrode GE1, the storage line STL and the second gate electrode GE2, respectively. The first gate electrode GE1 is protruded from the gate line GL, so that the barrier pattern 111 is formed beneath the gate line GL in substantially the same way as the first gate electrode GE1.

Accordingly, the barrier patterns 111, 113 and 117 that are patterned in substantially the same way as when forming the first conductive pattern on the SLG substrate 101, so that malfunctions due to adhesive foreign matter may be decreased.

For example, when the foreign matter is adhered to a surface of the SLG substrate 101, the barrier layer is formed on the SLG substrate 101 to strengthen the adhesive strength between the SLG substrate 101 and the first conductive pattern. In this case, when heat is generated due to additional processes, a gas may flow from a portion to which the foreign matter is adhered, so that the barrier layer is exploded. Accordingly, the lines formed on the barrier layer may be disconnected or be released. Thus, the barrier layer is patterned in substantially the same way as the first conductive pattern to decrease the area of the barrier layer, so that malfunctions due to the adhesive foreign matter may be decreased.

A gate insulation layer 130 is formed on the SLG substrate 101 on which the first conductive pattern is formed. A first semiconductor pattern 141 of the first switching element TR1 and a second semiconductor pattern 142 of the second switching element TR2 are formed on the gate insulation layer 130. The first and second semiconductor patterns 141 and 142 include an active layer 140a doped with impurities and a resistant contact layer 140b formed on the active layer 140a, respectively.

A second conductive pattern is formed on the SLG substrate 101 on which the first and second semiconductor patterns 141 and 142 are formed. The second conductive pattern includes a data line DL crossing the gate line GL, a first source electrode SE1 of the first switching element TR1, a first drain electrode DE1 of the first switching element TR1, a second source electrode SE2 of the second switching element TR2 and a second drain electrode DE2 of the second switching element TR2. The data line DL, the first source electrode SE1 and the first drain electrode DE1 are formed in the pixel area PA. The second source electrode SE2 and the second drain electrode DE2 are formed in the gate circuit area GCA.

A protective insulation layer 160 is formed on the SLG substrate 101 on which the second conductive pattern is formed. A pixel electrode PE electrically connected to the first drain electrode DE1 is formed on the protective insulation layer 160.

FIGS. 4 to 7 are cross-sectional views illustrating a process for manufacturing the display substrate in FIG. 3.

Referring to FIGS. 3 and 4, the display substrate 100 includes the SLG substrate 101. The barrier layer 110 is formed on the SLG substrate 101. The barrier layer 110 includes, for example, transparent or opaque materials. The barrier layer 110 may include, for example, one of a metal material, a metal compound, a transparent conductive material and an insulating material. For example, the barrier layer 110 may include one of molybdenum, a-ITO, ITO, IZO, SiNx, SiOx and a metal compound. The metal compound may be, for example, one of a metal oxide, a metal nitride, a metal boride and a metal carbide. The thickness of the barrier layer 110 may be between about 50 Å and about 2,000 Å.

A first conductive layer 120 is formed on the barrier layer 110. The first conductive layer 120 may include, for example, at least one of chromium (Cr), chromium (Cr) alloy, molybdenum (Mo), molybdenum-nitride (MoN), molybdenum-niobium (MoNb), molybdenum (Mo) alloy, copper (Cu), copper (Cu) alloy, copper-molybdenum (CuMo) alloy, aluminum (Al), aluminum (Al) alloy, silver (Ag) and silver (Ag) alloy.

A photoresist layer is formed on the SLG substrate 101 on which the first conductive layer 120 is formed, and then the photoresist layer is patterned using a mask to leave a photoresist pattern PR in a first area MA1 in which the first conductive pattern is formed.

The first conductive pattern includes the gate line GL, the first gate electrode GE1, the storage line STL and the second gate electrode GE2. The barrier layer 110 and the first conductive layer 120 are patterned using the photoresist pattern PR to form the first conductive pattern on the SLG substrate 101.

When the barrier layer 110 includes the metal material such as, for example, a-ITO, IZO and molybdenum (Mo), the barrier layer 110 and the first conductive layer 120 may be patterned, for example, by a wet etching at the same time. However, when the barrier layer 110 includes the insulating material and the metal compound, the barrier layer 110 may be patterned by, for example, a dry etching and the first conductive layer 120 may be patterned by, for example, the wet etching.

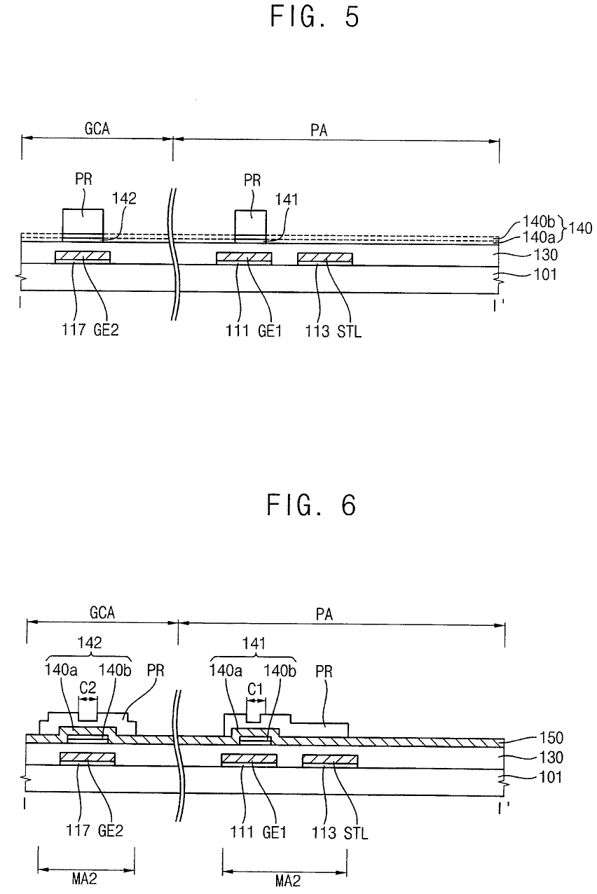

Referring to FIGS. 3 and 5, the barrier patterns are formed between the first conductive pattern and the SLG substrate 101 to correspond to the first conductive pattern. For example, the barrier patterns 111, 113 and 117 are formed between the first gate electrode GE1, the storage line STL and the second gate electrode GE2 and the SLG substrate 101, respectively.

The area of the barrier layer 110 formed on the SLG substrate 101 may be decreased, so that malfunctions due to the foreign matter adhered between the SLG substrate 101 and the barrier layer 110 may be decreased. In addition, the barrier layer 110 is patterned to enhance the light transmissivity of the display substrate 100.

The gate insulation layer 130 is formed on the SLG substrate 101 on which the first conductive pattern is formed. The first and second semiconductor patterns 141 and 142 are formed on the SLG substrate 101 on which the gate insulation layer 130 is formed. The semiconductor layer 140 including the active layer 140a doped with the impurities and the resistant contact layer 140b is formed on the gate insulation layer 130. The semiconductor layer 140 is patterned using the photoresist pattern PR to form the first and second semiconductor patterns 141 and 142 on the first and second gate electrodes GE1 and GE2.

Referring to FIGS. 3 and 6, a second conductive layer 150 is formed on the SLG substrate 101 on which the first and second semiconductor patterns 141 and 142 are formed. The second conductive layer 150 may be, for example, a metal material including at least one of molybdenum (Mo), molybdenum-nitride (MoN), molybdenum-niobium (MoNb), molybdenum (Mo) alloy, copper (Cu), copper (Cu) alloy, copper-molybdenum (CuMo) alloy, aluminum (Al), aluminum (Al) alloy, silver (Ag) and silver (Ag) alloy.

The photoresist layer is formed on the SLG substrate 101 on which the second conductive layer 150 is formed, and the photoresist layer is patterned using, for example, a slit mask, so that the photoresist pattern PR is formed on the area in which the second conductive pattern is formed. The second conductive pattern includes the data line DL, the first source electrode SE1, the first drain electrode DE1, the second source electrode SE2 and the second drain electrode DE2. Thus, the photoresist pattern PR has a first thickness in an area in which the second conductive pattern is formed, and has a second thickness in an area correspond to a channel area of the first and second switching elements TR1 and TR2. The first thickness is thicker than the second thickness.

The data line DL, an electrode pattern of the first switching element TR1 and an electrode pattern of the second switching element TR2 are formed by patterning the second conductive layer 150 using the photoresist pattern PR. Then, the photoresist pattern PR is eliminated by a constant thickness to expose the electrode patterns on the channel areas C1 and C2 of the first and second switching elements TR1 and TR2, and to leave the photoresist pattern PR on the second conductive pattern. The electrode patterns on the channel areas C1 and C2 are patterned using the remaining photoresist pattern PR, to form the first source electrode SE1 and the first drain electrode DE1 separated from each other and to form the second source electrode SE2 and the second drain electrode DE2 separated from each other. Accordingly, the first and second switching elements TR1 and TR2 are completed.

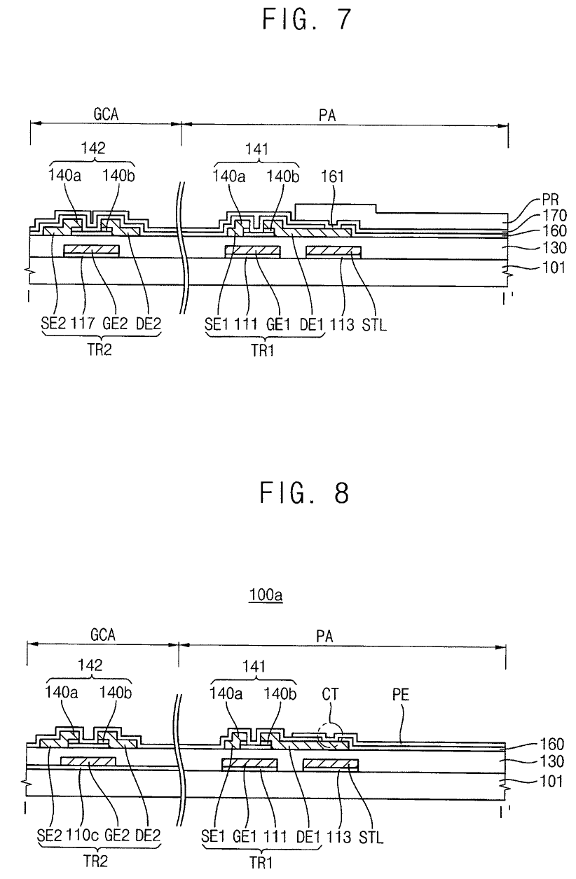

Referring to FIGS. 3 and 7, the protective insulation layer 160 is formed on the SLG substrate 101 on which the first and second switching elements TR1 and TR2 are formed. The protective insulation layer 160 is etched to form a contact hole 161 to expose the first drain electrode DE1 through the contact hole 161.

A third conductive layer 170 is formed on the SGL substrate 101 through which the contact hole 161 is formed. For example, the third conductive layer 170 may include the transparent conductive material such as IZO, ITO and a-ITO. The photoresist layer is formed on the third conductive layer 170, and the photoresist layer is patterned using the mask to form the photoresist pattern PR. The third conductive layer 170 is patterned using the photoresist pattern PR to form a third conductive pattern including the pixel electrode PE.

### Exemplary Embodiment 2

FIG. 8 is a cross-sectional view illustrating a display substrate according to Exemplary Embodiment 2 of the present invention. The display substrate according to the present exemplary embodiment is substantially the same as the display substrate in Exemplary Embodiment 1 except for a circuit barrier pattern formed in the gate circuit area. Thus, the same reference numerals will be used to refer to the same or like parts as those described in Exemplary Embodiment 1 and any further repetitive explanation concerning the above elements will be omitted.

Referring to FIG. 8, the SLG substrate 101 includes the pixel area PA in which the pixel portion P is formed, and the gate circuit area GCA in which the gate circuit part is formed.

The barrier patterns are formed on the SLG substrate 101. The barrier patterns 111 and 113 patterned in substantially the same way as the first conductive pattern are formed in the pixel area PA to decrease the area of the barrier layer. Thus, malfunctions due to the adhesive foreign matter may be decreased.

A circuit barrier pattern 110c is entirely formed in the gate circuit area GCA. The circuit barrier pattern 110c strengthens the adhesive strength between the SLG substrate 101 and the gate circuit part formed on the SGL substrate 101.

When the gate circuit part is driven, the heat is generated in itself and the heat accelerates the flow of the alkali ions of the SLG substrate 101, so that the adhesive strength between the gate circuit part and the SLG substrate 101 may be weakened. For example, the area of the second semiconductor pattern 142 of the second switching element TR2 is larger than that of the first semiconductor pattern 141 of the first switching element TR1, so that the temperature of the heat generated by an electric signal is higher in the gate circuit area GCA than in the pixel area PA. Accordingly, the adhesive strength between the gate circuit part and the SLG substrate 101 may be weakened.

Thus, the circuit barrier pattern 110c is entirely formed in the gate circuit area GCA, to strengthen the adhesive strength between the gate circuit part and the SLG substrate 101.

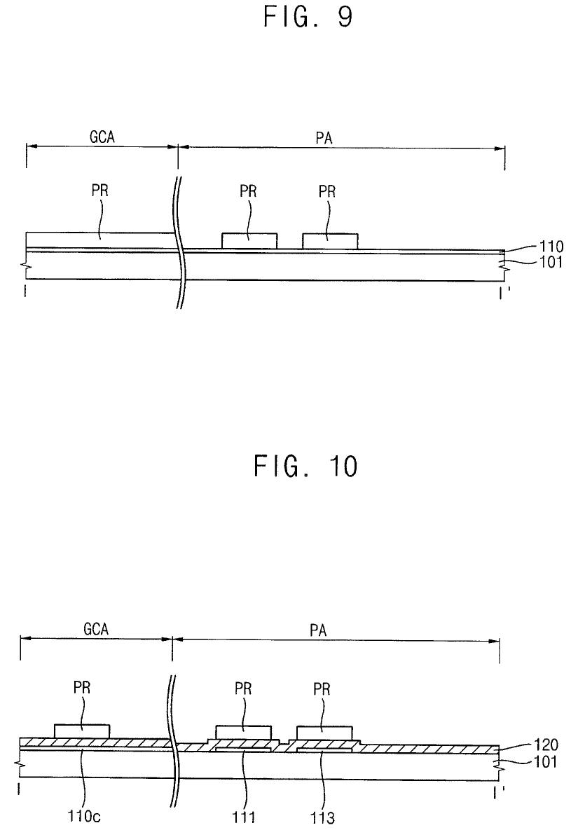

FIGS. 9 to 11 are cross-sectional views illustrating a process for manufacturing the display substrate in FIG. 8.

Referring to FIGS. 8 and 9, the display substrate 100a includes the SLG substrate 101. The barrier layer 110 is formed on the SLG substrate 101. The barrier layer 110 includes, for example, transparent and opaque materials. The barrier layer 110 may include, for example, one of a metal material, a metal compound, a transparent conductive material and an insulating material. For example, the barrier layer 110 may include one of molybdenum, a-ITO, ITO, IZO, SiNx, SiOx and the metal compound. The metal compound may include, for example, one of a metal oxide, a metal nitride, a metal boride and a metal carbide. The thickness of the barrier layer 110 may be between about 50 Å and about 2,000 Å.

The photoresist layer is formed on the SLG substrate 101 on which the barrier layer 110 is formed, and the photoresist layer is patterned using the mask to form the photoresist pattern PR. The photoresist pattern PR is formed in the area of the pixel area PA in which the first conductive pattern, for example the gate line GL, the first gate electrode GE1 and the storage line STL, is formed. The photoresist pattern PR is entirely formed in the gate circuit area GCA.

Referring to FIGS. 8 and 10, the barrier layer 110 is patterned using the photoresist pattern PR, to form the barrier patterns 111 and 113 and the circuit barrier pattern 110c. The barrier patterns 111 and 113 are formed in the pixel area PA, to correspond to the area in which the gate line GL, the first gate electrode GE1 and the storage line STL are formed. The circuit barrier pattern 110c is entirely formed in the gate circuit area GCA.

The first conductive layer 120 is formed on the SLG substrate 101 on which the barrier patterns 111 and 113 and the circuit barrier pattern 110c are formed. The photoresist layer is formed on the first conductive layer 120, and the photoresist layer is patterned using the mask, to form the photoresist pattern PR on the first conductive layer 120. The photoresist pattern PR is formed in the area in which the first conductive pattern is formed, for example the first area MA1. The photoresist pattern PR is formed in the area of the pixel area PA in which the gate line GL, the first gate electrode GE1 and the storage line STL are formed. The photoresist pattern PR is formed in the area of the gate circuit area GCA in which the second gate electrode GE2 is formed.

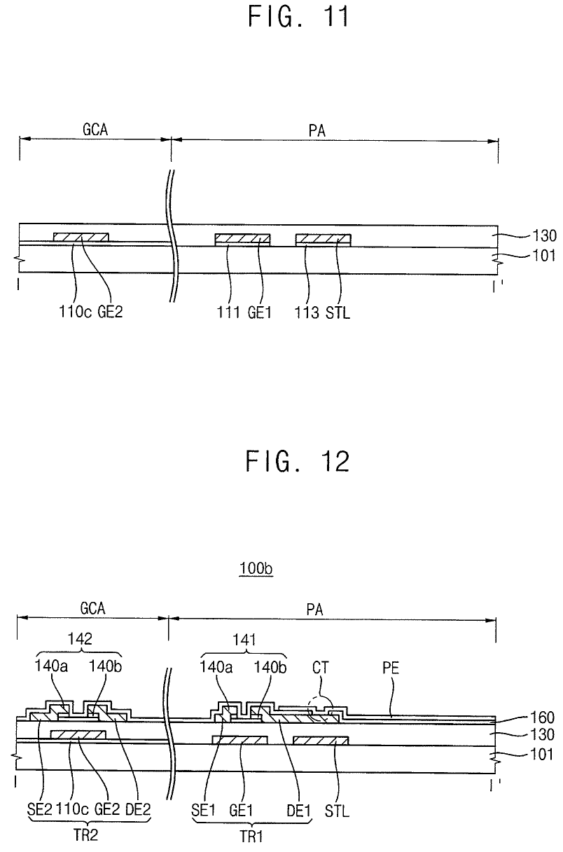

Referring to FIGS. 8 and 11, the first conductive layer 120 is patterned using the photoresist pattern PR to form the first conductive pattern, the gate line GL, the first gate electrode GE1, the storage line STL and the second gate electrode GE2. The gate insulation layer 130 is formed on the SLG substrate 101 on which the first conductive pattern is formed.

The process of forming the semiconductor patterns 141 and 142, the second conductive pattern including the data line DL and the third conductive pattern including the pixel electrode PE on the SLG substrate 101, is substantially the same as the process explained in FIGS. 5 to 7, and thus any further repetitive explanation concerning the above process will be omitted.

### Exemplary Embodiment 3

FIG. 12 is a cross-sectional view illustrating a display substrate according to Exemplary Embodiment 3 of the present invention. The display substrate according to the present exemplary embodiment is substantially the same as the display substrate in Exemplary Embodiment 2 except for a first conductive pattern formed in the pixel area. Thus, the same reference numerals will be used to refer to the same or like parts as those described in Exemplary Embodiment 2 and any further repetitive explanation concerning the above elements will be omitted.

Referring to FIG. 12, the display substrate 100b includes the pixel area PA in which the pixel portion P is formed, and the gate circuit area GCA in which the gate circuit part is formed.

The circuit barrier pattern 110c is formed on the SLG substrate 101 to correspond to the gate circuit area GCA. The barrier pattern may not be formed in the pixel area PA.

The gate circuit part is formed in the gate circuit area GCA. When the gate circuit part is driven, the heat generated from the gate circuit part accelerates the generation of the alkali ions from the LSG substrate 101, so that the adhesive strength between the SLG substrate 101 and the gate circuit part may be weakened. The circuit barrier pattern 110c is entirely formed in the gate circuit area GCA to strengthen the adhesive strength between the SLG substrate 101 and the gate circuit part.

In the pixel area PA, the first conductive pattern, the gate line GL, the first gate electrode GE1 and the storage line STL are directly formed on the SLG substrate 101. The barrier pattern may not be formed in the pixel area PA, so that malfunctions due to the adhesive foreign matter may be prevented and the light transmissivity may be enhanced.

FIG. 13 is a graph illustrating a correlation between a voltage between drain and source electrodes and the resistance of a gate electrode.

Referring to FIG. 13, a first graph A illustrates a variation of the resistance Rg of the gate electrode with respect to the voltage Vds between the drain and source electrodes in a panel including the SLG substrate without the barrier layer. A second graph B illustrates a variation of the resistance Rg of the gate electrode with respect to the voltage Vds between the drain and source electrodes in the panel including the SLG substrate with the barrier layer.

Comparing the first graph A to the second graph B, the resistance Rg of the gate electrode in the panel including the SLG substrate without the barrier layer is substantially the same as that in the panel including the SLG substrate with the barrier layer. Thus, when the display panel is driven, the heat and an electric field generated from the pixel area PA are much smaller than those generated from the gate circuit area GCA. Thus, difficulties such as disconnecting and breaking of lines that are caused by weakening of the adhesive strength due to the alkali ions, may be significantly decreased. Accordingly, the barrier pattern may not be formed in the pixel area PA.

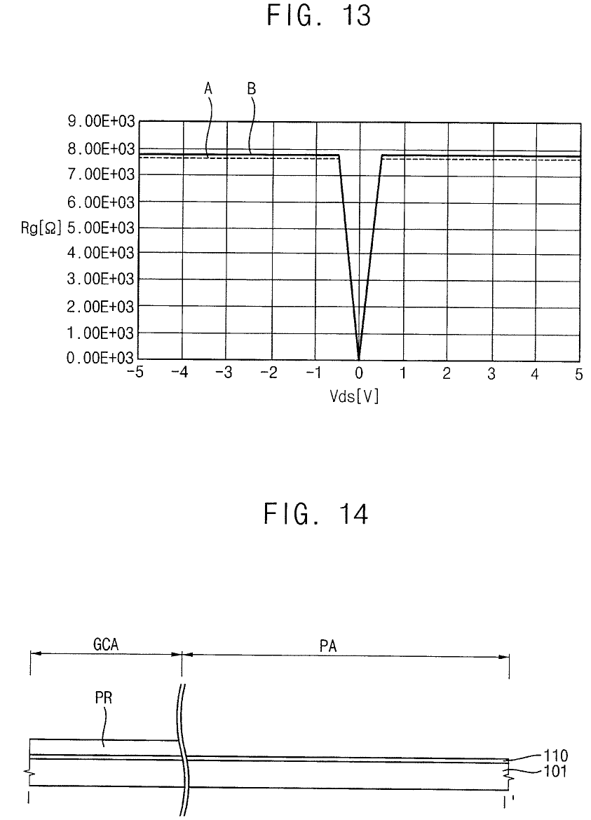

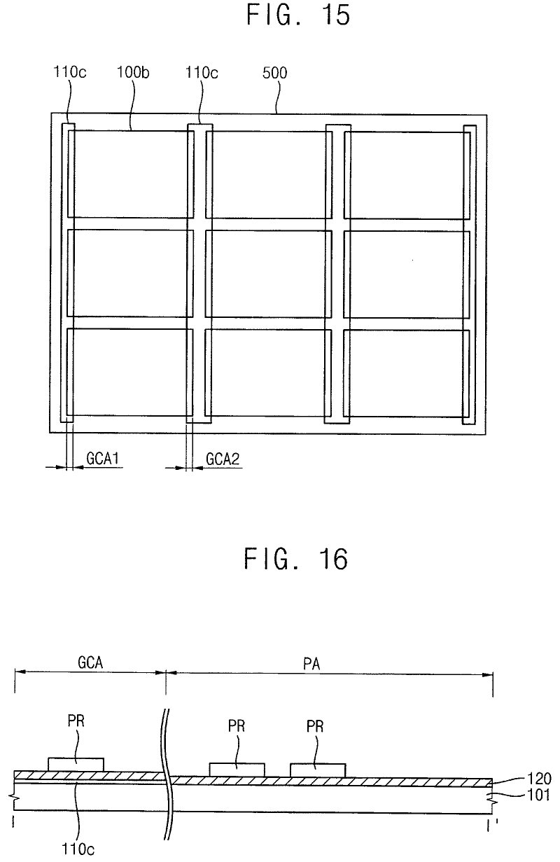

FIGS. 14 to 17 are cross-sectional views and plan views illustrating a process for manufacturing the display substrate in FIG. 12.

Referring to FIGS. 12 and 14, the display substrate 100a includes the SLG substrate 101. The barrier layer 110 is formed on the SLG substrate 101. The barrier layer 110 includes, for example, conductive material, non-conductive material, transparent material or opaque material. For example, the barrier layer 110 may include, for example, one of a metal material, a metal compound, a transparent conductive material and an insulating material. For example, the barrier layer 110 may include one of a metal oxide, a metal nitride, a metal boride and a metal carbide. The thickness of the barrier layer 110 may be between about 50 Å and about 2,000 Å.

The photoresist layer is formed on the SLG substrate 101 on which the barrier layer 110 is formed, and the photoresist layer is patterned using the mask to form the photoresist pattern PR. The photoresist pattern PR is entirely formed in the gate circuit area GCA, and may not be formed in the pixel area PA.

Referring to FIGS. 12 and 15, a mother substrate includes a plurality of unit cells like the display substrate 100c. The circuit barrier pattern 110c patterned by the photoresist pattern PR is formed on the mother substrate 500. The circuit barrier pattern 110c is formed to correspond to the gate circuit areas GCA1 and GCA2 of the display substrate 100c.

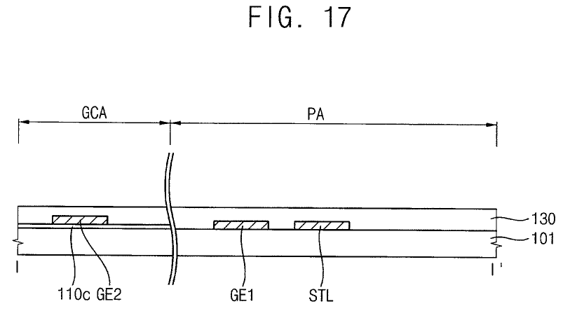

Referring to FIGS. 12 and 16, the first conductive layer 120 is formed on the SLG substrate 101 in which the circuit barrier pattern 110c is formed, to correspond to the gate circuit area GCA. The photoresist layer is formed on the first conductive layer 120, and the photoresist layer is patterned using the mask, to form the photoresist pattern PR on the first conductive layer 120. The photoresist pattern PR is formed in the first area MA1 in which the first conductive pattern is formed. The photoresist pattern PR is formed in the area of the pixel area PA in which the gate line GL, the first gate electrode GE1 and the storage line STL are formed. The photoresist pattern PR is formed in the area of the gate circuit area GCA in which the second gate electrode GE2 is formed.

Referring to FIGS. 12 and 17, the first conductive pattern is formed by patterning the first conductive layer 120 using the photoresist pattern PR. The gate line GL, the first gate electrode GE1 and the storage line STL are formed to make contact with the SLG substrate 101 in the pixel area PA. The second gate electrode GE2 is formed on the circuit barrier pattern 110c in the gate circuit area GCA. The gate insulation layer 130 is formed on the SLG substrate 101 on which the first conductive pattern is formed.

Then, the processes of forming the second conductive pattern including the semiconductor patterns 141 and 142 and the data line DL, and the third conductive pattern including the pixel electrode PE on the SLG substrate 101, are substantially the same as the processes in FIGS. 5 to 7, and thus any further repetitive explanation will be omitted.

According to exemplary embodiments of the present invention, the area of a soda-lime glass substrate in which a barrier layer is formed may be decreased, so that malfunctions due to foreign matter adhered to the soda-lime glass substrate may be decreased. In addition, the barrier layer may not be formed in the pixel area to thereby enhance light transmissivity.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A display substrate comprising:
a soda-lime glass substrate having a pixel area;
a first conductive pattern including a gate line, the gate line being formed on the soda-lime glass substrate and being formed from a first conductive layer;
a barrier pattern formed between the first conductive pattern and the soda-lime glass substrate;
a second conductive pattern including a data line crossing the gate line, the data line being formed on the first conductive pattern and being formed from a second conductive layer; and
a third conductive pattern including a pixel electrode formed in the pixel area of the soda-lime glass substrate, the pixel electrode being formed on the second conductive pattern and being formed from a third conductive layer.

2. The display substrate of claim 1, wherein the first conductive pattern further comprises:
a gate electrode of a first switching element protruded from the gate line; and
a storage line formed in the pixel area.

3. The display substrate of claim 1, wherein the soda-lime glass substrate has a gate circuit area, and a gate circuit part applying a driving signal to the gate line is formed in the gate circuit area.

4. The display substrate of claim 3, wherein the first conductive pattern includes a gate electrode of a second switching element forming the gate circuit part and a line.

5. The display substrate of claim 3, further comprising a circuit barrier pattern formed in a circuit area on the soda-lime glass substrate.

6. The display substrate of claim 5, wherein the barrier pattern and the circuit barrier pattern each include one of an opaque material or a transparent material.

7. The display substrate of claim 5, wherein the barrier pattern and the circuit barrier pattern each include one of a conductive material or a non-conductive material.

8. A display substrate comprising:
a soda-lime glass substrate having a plurality of pixel areas;
a gate line formed by making direct contact with the soda-lime glass substrate;
a gate circuit part applying a driving signal to the gate line;
a circuit barrier pattern disposed between the gate circuit part and the soda-lime glass substrate;
a data line crossing the gate line; and
a pixel electrode formed in each of the pixel areas.

9. The display substrate of claim 8, wherein the circuit barrier pattern includes one of an opaque material, a transparent material, a conductive material, or a non-conductive material.

10. A method for manufacturing a display substrate, the method comprising:
forming a barrier layer and a first conductive layer on a soda-lime glass substrate, wherein the soda-lime glass substrate includes a pixel area;
forming a first conductive pattern having a gate line and a barrier pattern between the first conductive pattern and the soda-lime glass substrate by patterning the barrier layer and the first conductive layer using substantially the same mask;
forming a second conductive pattern including a data line crossing the gate line, the data line being formed on the first conductive pattern and being formed from a second conductive layer; and
forming a third conductive pattern including a pixel electrode formed in the pixel area of the soda-lime glass substrate, the pixel electrode being formed on the second conductive pattern and being formed from a third conductive layer.

11. The method of claim 10, wherein the first conductive pattern further comprises a gate electrode of a first switching element protruded from the gate line and a storage line formed in the pixel area.

12. The method of claim 10, wherein the soda-lime glass substrate has a gate circuit area in which a gate circuit part applying a driving signal to the gate line is formed, and the first conductive pattern includes a gate electrode of a second switching element forming the gate circuit part and a line.

13. The method of claim 10, wherein the barrier layer includes one of an opaque material or a transparent material.

14. The method of claim 10, wherein the barrier layer includes one of a conductive material or a non-conductive material.

15. A method for manufacturing a display substrate, the method comprising:
forming a barrier layer on a soda-lime glass substrate, the soda-lime glass substrate having a display area, a gate circuit area in which a gate circuit part is formed and a pixel area;
forming a circuit barrier pattern in the gate circuit area, by patterning the barrier layer;
forming a first conductive pattern including a gate line, the gate line being formed on the soda-lime glass substrate having the circuit barrier pattern formed thereon and being formed from the first conductive layer;
forming a second conductive pattern including a data line crossing the gate line, the data line being formed on the soda-lime glass substrate having the first conductive pattern formed thereon and being formed from the second conductive layer; and
forming a third conductive pattern including a pixel electrode formed in the pixel area of the soda-lime glass substrate, the pixel electrode being formed on the second conductive pattern and being formed from a third conductive layer.

16. The method of claim 15, wherein the first conductive pattern of the display area is formed by making direct contact with the soda-lime glass substrate.

17. The method of claim 15, wherein the forming of the circuit barrier pattern further comprises forming a barrier pattern to correspond to an area of the display area in which the first conductive pattern is formed.

18. The method of claim 17, wherein the barrier pattern is disposed between the first conductive pattern in the display area and the soda-lime glass substrate.

19. The method of claim 15, wherein the barrier layer includes an opaque material.

20. The method of claim 15, wherein the barrier layer includes a conductive material.
